(19) United States
(12) Patent Application Publication
(10) Pub. No.: US 2009/0127682 A1
(43) Pub. Date: May 21, 2009

(54) CHIP PACKAGE STRUCTURE AND METHOD OF FABRICATING THE SAME

(75) Inventors: Hyeongno Kim, Kyunggi-Do (KR); Sung-Ho Youn, Kyunggi-Do (KR)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/941,309

(22) Filed: Nov. 16, 2007

(51) Int. Cl. H01L 23/495; H01L 21/58

(52) U.S. Cl. 257/676; 438/118; 257/E21.506; 257/E23.031

(57) ABSTRACT

A method of fabricating a chip package structure is provided. A metallic plate having a first surface, a second surface, and a first patterned metallic layer formed on the first surface thereof is provided. A half-etching process is performed to form first recesses on the first surface of the metallic plate, wherein leads are defined on the metallic plate by the first recesses. A first insulating material fills in each of the first recesses. A second patterned metallic layer is formed on the second surface of the metallic plate. A half-etching process is performed to form second recesses on the second surface of the metallic plate. The second recesses correspond to the first recesses, respectively, and expose the first insulating material inside the first recesses, such that the leads are electrically isolated from one another. A chip is placed on the metallic plate and electrically connected thereto.

### BACKGROUND OF THE INVENTION

1. Field of the Invention

The present invention generally relates to a chip package structure and a method of fabricating the same, and more particularly, to a chip package structure with a hybrid chip carrier and a method of fabricating the same.

2. Description of Related Art

In the semiconductor industry, the fabrication of integrated circuits (IC) may be divided into three major stages: IC design stage, IC process stage and IC package stage.

In the fabrication of IC, the steps of producing a chip include at least wafer fabrication, IC formation and wafer sawing. The wafer has an active surface, in which active elements are formed. After the fabrication of IC in the wafer is completed, a plurality of bonding pads is disposed on the active surface of the wafer so that the chip subsequently cut out from the wafer may be electrically connected to a carrier through the bonding pads. The carrier is a lead frame or a package substrate, for example. The chip may be connected to the carrier by wire bonding or flip-chip bonding so that the bonding pads of the chip may be electrically connected to the contacts of the carrier to form a chip package.

FIGS. 1A˜1E are schematic cross-sectional views illustrating the process for fabricating a semiconductor device disclosed in Japanese Patent Application Publication No. 2005-317998. First, referring to FIG. 1A, a copper foil 21 having a first patterned metallic layer 22 and a second patterned metallic layer 23 is provided. The first patterned metallic layer 22 serving as electrical contacts and the second patterned metallic layer 23 are formed on an upper surface and a bottom surface of the copper foil 21, respectively. Please refer to FIG. 1B, an etching resistance layer 24 is formed on the bottom surface of the copper foil 21, and then a half-etching process is performed on the upper surface of the copper foil 21 by using the first patterned metallic layer 22 as an etching mask to form a plurality of recesses R on the upper surface of the copper foil 21. Then, referring to FIG. 1C, a semiconductor device 11 is fixed on one of the recesses serving as a die pad by using an adhesive layer 20, and a plurality of conductive wires 16 are formed between the semiconductor device 11 and the wire bonding portions 12 of the copper foil 21. Next, referring to FIG. 1D, a second insulating material 18 is formed on the upper surface of the copper foil 21 to encapsulate the semiconductor device 11, the conductive wires 16, and the upper surface of the copper foil 21. Then, referring to FIG. 1E, a back etching process is performed on the bottom surface of the copper foil 21 by using the second patterned metallic layer 23 as an etching mask to form a chip package structure 10 having area array leads.

In the fabricating process of the chip package structure disclosed in Japanese Patent Application Publication No. 2005-317998, a back etching process is required for completing the packaging process. However, the back etching process may damage the chip, and this may result in a lower yield rate of the chip package structure. Accordingly, the solution of how to improve the fabrication process of the semiconductor chip package is highly desired in the semiconductor technology.

### SUMMARY OF THE INVENTION

Accordingly, the present invention is directed to a chip package structure and a method of fabricating the same. In the method of fabricating a chip package structure provided by the present invention, there is no need to perform a back etching process after the chip is disposed on the chip carrier, and therefore the chip is protected from being damaged due to the back etching process, thus enhancing the yield rate of the chip package structure.

The present invention is directed to a method of fabricating a chip package structure comprising the following steps. A metallic plate having a first surface and a second surface opposite to the first surface is provided. The metallic plate comprises a first patterned metallic layer formed on the first surface thereof. Then, a half-etching process is performed on the first surface of the metallic plate by using the first patterned metallic layer as an etching mask to form a plurality of first recesses on the first surface of the metallic plate, wherein a plurality of leads are defined on the metallic plate by the first recesses. Next, a first insulating material is filled in each of the first recesses. Then, a second patterned metallic layer is formed on the second surface of the metallic plate. Afterward, a half-etching process is performed on the second surface of the metallic plate by using the second patterned metallic layer as an etching mask to form a plurality of second recesses on the second surface of the metallic plate. The second recesses are corresponding to the first recesses, respectively, and expose the first insulating material inside the first recesses, such that the leads are electrically isolated from one another. Then, a chip is placed on the metallic plate. Finally, the chip is electrically connected to the leads.

According to an embodiment of the present invention, the metallic plate is a copper foil.

According to an embodiment of the present invention, the first patterned metallic layer is a nickel/silver layer.

According to an embodiment of the present invention, the second patterned metallic layer is a nickel/silver layer.

According to an embodiment of the present invention, the chip is disposed on the first surface or the second surface of the metallic plate.

According to an embodiment of the present invention, the step of performing the half-etching process on the first surface of the metallic plate to form the first recesses on the first surface of the metallic plate further comprises defining a die pad on the metallic plate, and the die pad is surrounded by the leads.

According to an embodiment of the present invention, the chip is fixed on the die pad by using an adhesive layer.

According to an embodiment of the present invention, the step of electrically connecting the chip and the leads is forming a plurality of conductive wires between the chip and the leads, such that the chip is electrically connected to the leads through the conductive wires.

According to an embodiment of the present invention, the step of electrically connecting the chip and the leads is performed by using flip chip technology.

According to an embodiment of the present invention, after the step of electrically connecting the chip and the leads, the method further comprises a step of forming a second insulating material on the first surface of the metallic plate for encapsulating the chip and a plurality of conductive elements electrically connecting the chip and the leads.

The present invention also provides a chip package structure comprising a chip carrier, a chip, a plurality of conductive elements, a first insulating material, and a second insulating material. The chip carrier has a first surface and a second surface opposite to the first surface, wherein the chip carrier comprises a plurality of leads. The chip is disposed on the first surface of the chip carrier. The conductive elements are disposed between the chip and the leads so as to electrically connect the chip and the leads through the conductive components. The first insulating material fills between the leads such that the leads are electrically isolated from one another. The second insulating material encapsulates the first surface of the chip carrier, the chip, the conductive elements, and a surface of the first insulating material.

According to an embodiment of the present invention, the chip carrier further includes a die pad, and the die pad is surrounded by the leads.

According to an embodiment of the present invention, the chip has an active surface, a back surface, and a plurality of chip bonding pads on the active surface, and the back surface of the chip is fixed on the die pad.

According to an embodiment of the present invention, the conductive elements are a plurality of conductive wires connecting the chip bonding pads and the leads, respectively.

According to an embodiment of the present invention, the chip has an active surface and a plurality of chip bonding pads on the active surface, and the active surface faces the first surface of the chip carrier.

According to an embodiment of the present invention, the conductive elements are a plurality of bumps disposed between the leads and the chip bonding pads, respectively, such that the chip is electrically connected to the chip carrier through the bumps.

According to an embodiment of the present invention, the first insulating material fills between the leads and is near the first surface of the chip carrier.

According to an embodiment of the present invention, the first insulating material fills between the leads and is near the second surface of the chip carrier.

According to an embodiment of the present invention, the chip carrier further comprises a nickel/silver layer disposed on the first surface of the chip carrier.

According to an embodiment of the present invention, the chip carrier further comprises a nickel/silver layer disposed on the second surface of the chip carrier.

According to an embodiment of the present invention, a material of the first insulating material is different from that of the second insulating material.

In summary, the method of fabricating a chip package structure provided by the present invention utilizes the half-etching process and the step of filling the first insulating material in the recesses of the metallic plate to form the chip carrier with leads. Since there is no need to perform a back etching process after the chip is disposed on the chip carrier, therefore, the chip is protected from being damaged due to the back etching process, thus enhancing the yield rate of the chip package structure.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1E are schematic cross-sectional views illustrating the process for fabricating a semiconductor device disclosed in Japanese Patent Application Publication No. 2005-317998.

FIGS. 2A˜2H are schematic cross-sectional views showing the process for fabricating a chip package structure according to an embodiment of the present invention.

FIG. 3 is a schematic cross-sectional view showing the chip package structure with the metallic plate arranged in a reverse manner.

FIGS. 4A˜4C are schematic cross-sectional views showing the process for fabricating a chip package structure according to another embodiment of the present invention.

FIG. 5 is a schematic cross-sectional view showing the chip package structure with the metallic plate arranged in a reverse manner.

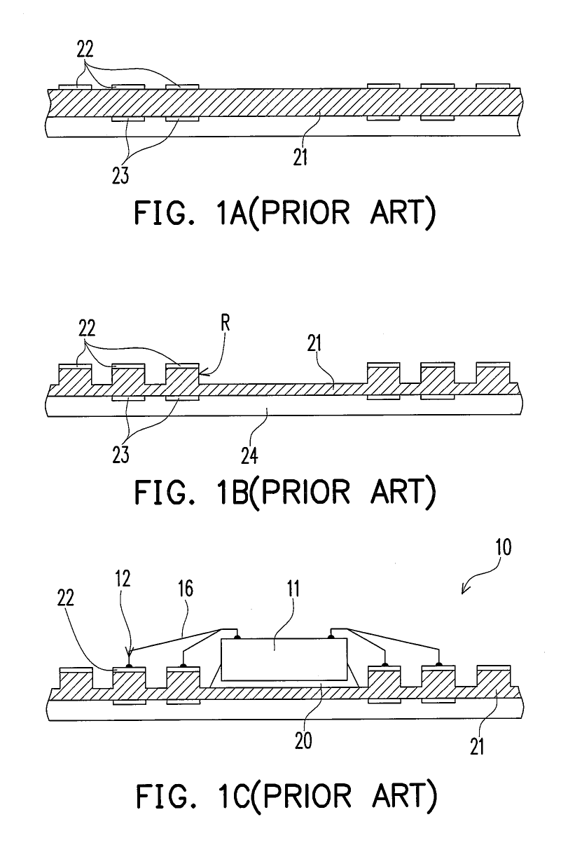

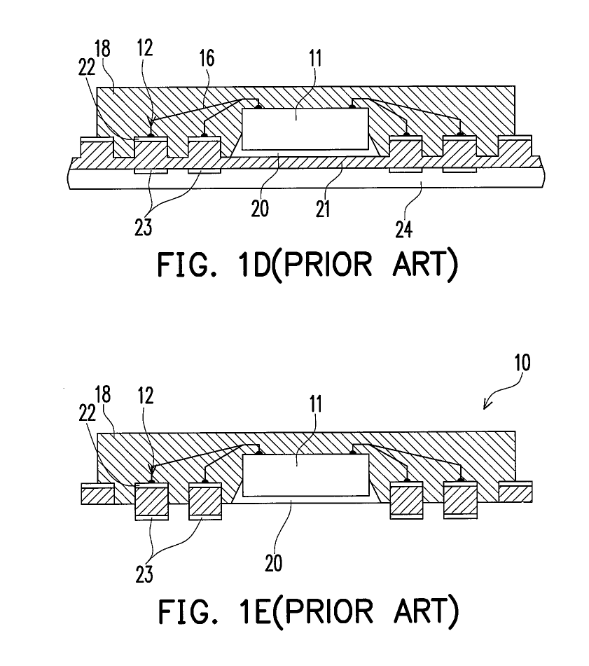

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

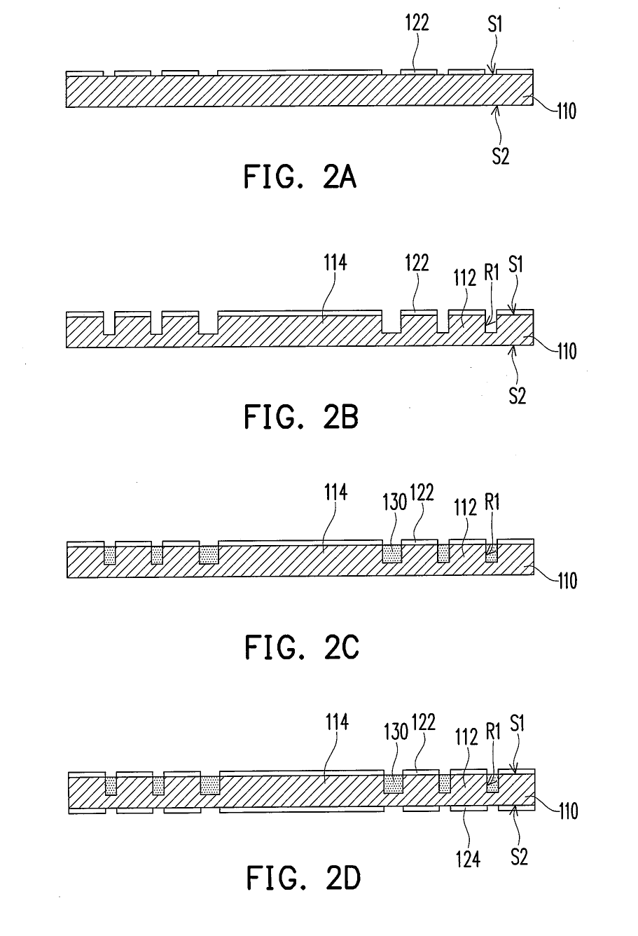

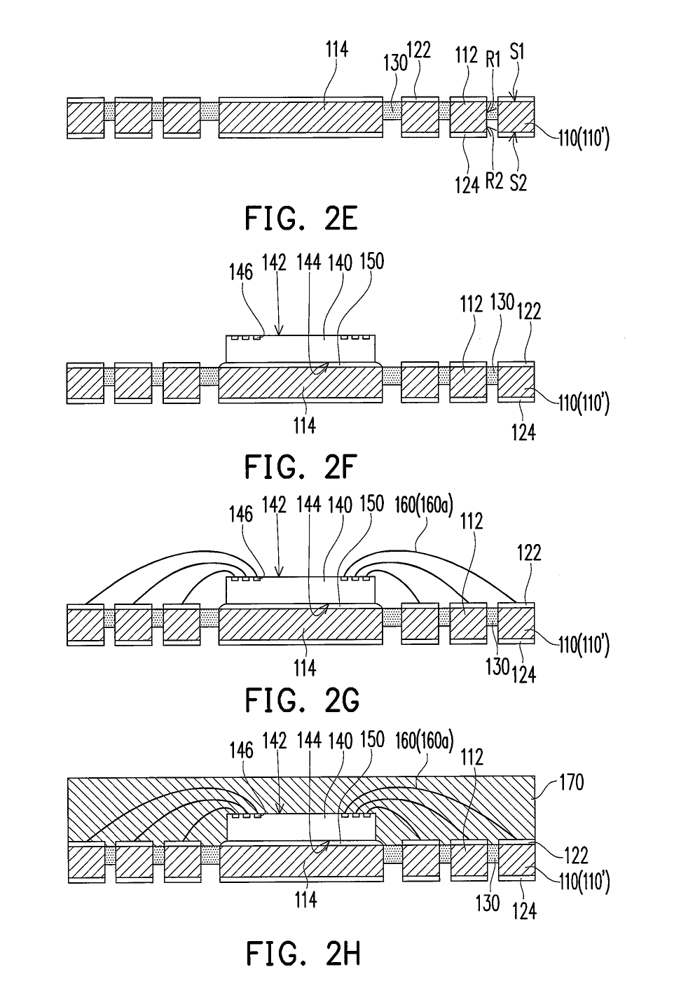

FIGS. 2A˜2H are schematic cross-sectional views showing the process for fabricating a chip package structure according to an embodiment of the present invention. In this embodiment, a method of fabricating a chip package structure using wire bonding technology for electrically connecting a chip and a chip carrier is taken as an example for illustration. However, the chip may be electrically connected to the chip carrier by using flip chip technology or other manner, and this would be illustrated in another embodiment.

First, referring to FIG. 2A, a metallic plate 110 having a first surface S1 and a second surface S2 opposite to the first surface S1 is provided. The metallic plate 110 comprises a first patterned metallic layer 122 formed on the first surface S1 of the metallic plate 110. In one embodiment of the present invention, the metallic plate 110 is a copper foil, and the first patterned metallic layer 122 is a nickel/silver layer formed by electroplating. Next, referring to FIG. 2B, a half-etching process is performed on the first surface S1 of the metallic plate 110 by using the first patterned metallic layer 122 as an etching mask to form a plurality of first recesses R1 on the first surface S1 of the metallic plate 110, such that a plurality of leads 112 are defined on the metallic plate 110 by the first recesses R1. In this embodiment, the step as shown in FIG. 2B further comprises defining a die pad 114 on first surface S1 of the metallic plate 110, and the die pad 114 is surrounded by the leads 112. Then, referring to FIG. 2C, a first insulating material 130 fills in each of the first recesses R1. The material of the first insulating material 130 may be resin or other suitable material.

Next, referring to FIG. 2D, a second patterned metallic layer 124 is formed on the second surface S2 of the metallic plate 110. Similarly, the second patterned metallic layer 124 may be a nickel/silver layer formed by electroplating. Then, referring to FIG. 2E, a half-etching process is performed on the second surface S2 of the metallic plate 110 by using the second patterned metallic layer 124 as an etching mask to form a plurality of second recesses R2 on the second surface S2 of the metallic plate 110, such that the metallic plate 110 may serve as a chip carrier 110′. As shown in FIG. 2E, the second recesses R2 correspond to the first recesses R1, respectively, and expose the first insulating material 130 inside the first recesses R1, such that the leads 112 are electrically isolated from one another, and the die pad 114 is electrically isolated from the neighboring leads 112.

Next, referring to FIG. 2F, the first patterned metallic layer 122 on the die pad 114 is removed, and then a chip 140 (such as a semiconductor device) is placed on the chip carrier 110′. In this embodiment, the chip 140 has an active surface 142, a back surface 144, and a plurality of chip bonding pads 146 on the active surface 142, and the back surface 144 of the chip 140 is attached on the die pad 114 by using an adhesive layer 150. Finally, referring to FIG. 2G, the chip 140 is electrically connected to the leads 112. As shown in FIG. 2G, a plurality of conductive elements 160 (i.e. the conductive wires 160a) are formed between the chip bonding pads 146 and the leads 112 by using wire bonding technology, such that the chip 140 may be electrically connected to the leads 112 through the conductive wires 160a. Thus far, the chip package structure 100 is formed according to the above processes. Furthermore, the bottom of each of the leads 112 may serve as an electrical contact for electrically connecting to external devices.

Besides, to prevent the die pad 114, the leads 112, the chip 140, and the conductive wires 160a as shown in FIG. 2G from being damaged and contaminated, the step as shown in FIG. 2H may be performed. As shown in FIG. 2H, a second insulating material 170 is formed on the first surface S1 of the metallic plate 110 for encapsulating the chip 140, at least one surface of the first insulating material 130 and the conductive elements 160 (i.e. the conductive wires 160a) electrically connecting the chip 140 and the leads 112. Besides, the material of the second insulating material 170 is different from that of the first insulating material 130.

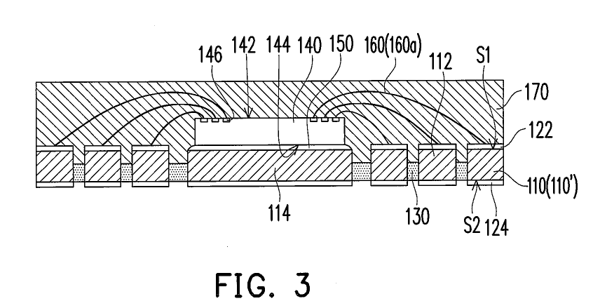

In this embodiment, the chip 140 is placed on the first surface S1 of the metallic plate 110. However, as shown in FIG. 3, the metallic plate 110 can be arranged in a reverse manner, such that the chip 140 is placed on the second surface S2 of the metallic plate 110. The position of the chip 140 relative to the metallic plate 110 is not limited in the present invention.

Referring to FIG. 2H again, the chip package structure 100 formed according to the above processes mainly comprises a chip carrier 110′, a chip 140, a plurality of conductive elements 160 (i.e. the conductive wires 160a), a first insulating material 130, and a second insulating material 170. The chip carrier 110′ has a first surface S1 and a second surface S2 opposite to the first surface S1. The chip carrier 110′ comprises a plurality of leads 112 defined by these first recesses R1. In this embodiment, the chip carrier 110′ further includes a die pad 114, and the die pad 114 is surrounded by the leads 112. The chip 140 is disposed on the first surface S1 of the chip carrier 110′. The conductive elements 160 (i.e. the conductive wires 160a) are disposed between the chip 140 and the leads 112 so as to electrically connect the chip 140 and the leads 112 through the conductive components. The first insulating material 130 fills between the leads 112 such that the leads 112 are electrically isolated from one another. The second insulating material 170 encapsulates the first surface S1 of the chip carrier 110′, the chip 140, the conductive elements 160 (i.e. the conductive wires 160a), and a surface of the first insulating material 130. The chip package structure 100 further comprises the first insulating material 130 filling between the leads 112 and near the first surface S1 of the chip carrier 110′. However, when the metallic plate 110 is arranged in a reverse manner as shown in FIG. 3, the first insulating material 130 is near the second surface S2 of the chip carrier 110′. Besides, the chip package structure 100 may further comprise a nickel/silver layer on the first surface S1 and/or the second surface S2 of the chip carrier 110′.

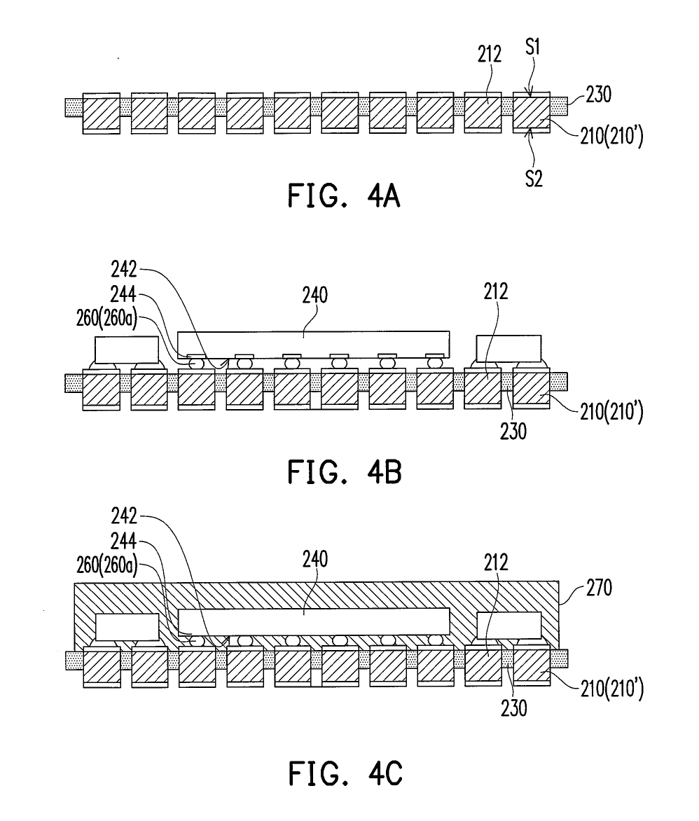

FIGS. 4A˜4C are schematic cross-sectional views showing the process for fabricating a chip package structure according to another embodiment of the present invention. In this embodiment, a method of fabricating a chip package structure using flip chip technology for electrically connecting a chip and a chip carrier is taken as an example for illustration. First, a metallic plate 210 formed according to the processes as shown in FIGS. 2A˜2E is provided. The difference between the chip carrier 100′ as shown in FIG. 2E and the chip carrier 210′ as shown in FIG. 4A is that the metallic plate 210 only comprises a plurality of leads 212. Then, referring to FIG. 4B, a chip 240 is placed on the metallic plate 210, and then the chip 240 is electrically connected to the metallic plate 210 by using flip chip technology. In this embodiment, the chip 240 has an active surface 242 and a plurality of chip bonding pads 244 on the active surface 242, and the active surface 242 faces the first surface S1 of the metallic plate 210. Besides, the chip 240 is electrically connected to the leads 212 through the conductive elements 260 (i.e. the bumps 260a) disposed therebetween.

Besides, to prevent the leads 212, the chip 240, and the bumps 260a as shown in FIG. 4B from being damaged and contaminated, the step as shown in FIG. 4C may be performed. As shown in FIG. 4C, a second insulating material 270 is formed on the first surface S1 of the metallic plate 210 for encapsulating the chip 240, a surface of the first insulating material 230 and the conductive elements 260 (i.e. the bumps 260a) electrically connecting the chip 240 and the leads 212. Besides, the material of the second insulating material 270 is different from that of the first insulating material 230.

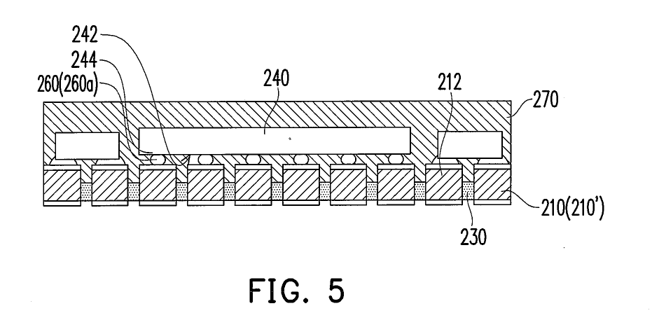

Similarly, as shown in FIG. 5, the metallic plate 210 can also be arranged in a reverse manner, such that the chip 240 is placed on the second surface S2 of the metallic plate 210. The position of the chip 240 relative to the metallic plate 210 is not limited in the present invention.

In summary, the method of fabricating a chip package structure provided by the present invention utilizes the half-etching process and the step of filling the first insulating material in the recesses of the metallic plate to form the hybrid chip carrier with leads. Then, the chip is placed on the chip carrier and electrically connected to the chip carrier, to form the chip package structure. Since there is no need to perform the back etching process after the chip is placed on the chip carrier, the chip is protected from being damaged due to the back etching process, thus enhancing the yield rate of the chip package structure.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

1-10. (canceled)

11. A chip package structure, comprising:
a chip carrier, having a first surface and a second surface opposite to the first surface, wherein the chip carrier comprises a plurality of leads;
a chip, disposed on the first surface of the chip carrier;
a plurality of conductive elements, disposed between the chip and the leads so as to electrically connect the chip and the leads through the conductive components;
a first insulating material, filling between the leads such that the leads are electrically isolated from one another; and
a second insulating material, encapsulating the first surface of the chip carrier, the chip, the conductive elements, and a surface of the first insulating material.

12. The chip package structure according to claim 11, wherein the chip carrier further includes a die pad, and the die pad is surrounded by the leads.

13. The chip package structure according to claim 12, wherein the chip has an active surface, a back surface, and a plurality of chip bonding pads on the active surface, and the back surface of the chip is attached on the die pad.

14. The chip package structure according to claim 13, wherein the conductive elements are a plurality of conductive wires connecting the chip bonding pads and the leads, respectively.

15. The chip package structure according to claim 11, wherein the chip has an active surface and a plurality of chip bonding pads on the active surface, and the active surface faces the first surface of the chip carrier.

16. The chip package structure according to claim 15, wherein the conductive elements are a plurality of bumps disposed between the leads and the chip bonding pads, respectively, such that the chip is electrically connected to the chip carrier through the bumps.

17. The chip package structure according to claim 11, wherein the first insulating material is filled between the leads and is near the first surface of the chip carrier.

18. The chip package structure according to claim 11, wherein the first insulating material is filled between the leads and is near the second surface of the chip carrier.

19. The chip package structure according to claim 11, wherein the chip carrier further comprises a nickel/silver layer disposed on the first surface of the chip carrier.

20. The chip package structure according to claim 11, wherein the chip carrier further comprises a nickel/silver layer disposed on the second surface of the chip carrier.

21. The chip package structure according to claim 11, wherein a material of the first insulating material is different from that of the second insulating material.
